(19) United States
(12) Patent Application Publication
(10) Pub. No.: US 2021/0408126 A1
(43) Pub. Date: Dec. 30, 2021

(54) COLOR FILTER COVER PLATE, PREPARATION METHOD THEREOF, AND DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Wenjie Li, Shenzhen, Guangdong (CN)

(21) Appl. No.: 16/615,699

(22) PCT Filed: Aug. 7, 2019
(86) PCT No.: PCT/CN2019/099593

§ 371 Date: Nov. 21, 2019

(30) Foreign Application Priority Data
May 30, 2019 (CN) 201910461131.2

(51) Int. Cl. H01L 27/32; G02B 5/20; H01L 51/52

(52) U.S. Cl. CPC H01L 27/322; H01L 51/5284; G02B 5/20

(57) ABSTRACT

The present invention provides a color filter cover plate, including a substrate layer. A plurality of light shielding strips are disposed on the substrate layer at intervals, and a color filter layer is disposed between the light shielding strips. A bank layer is disposed on the light shielding strip, and a metal layer is disposed on a side surface of each of the light shielding strips or the bank layer facing the color filter layer. The present invention provides a color filter cover plate which adopts a novel structural arrangement, which reduces the absorption of the lateral incident light, thereby effectively improving the light extraction efficiency of the display panel.

### FIELD OF INVENTION

The invention relates to the field of display technology, in particular to a color filter cover plate, a preparation method thereof, and a display panel.

### BACKGROUND OF INVENTION

It is known that organic light emitting diode (OLED) devices have been widely used in the industry due to their advantages such as self-luminous characteristic, high contrast, fast response times, and the flexible display panel.

The OLED devices for realizing full-color display generally have the following types: type A, adopting three kinds of organic light-emitting materials of red, green and blue to directly emit light; type B, adopting white organic light-emitting diode (WOLED) and color filter cover plate (color filter, CF); and type C, adopting a color conversion method, i.e. blue light emitting layer and a color conversion layer. Since type B can realize high number of pixels and large-size displays, it attracts much attention from the industry.

Although WOLEDs have a relatively high aperture ratio compared to other top emission display devices, light extraction efficiency and viewing angle of the devices are not good. Thus, in order to realize the full-color display, it is necessary to filter the white light emitted by the OLED with a color filter (CF).

The color filter design of the current OLED device is generally based on that of the liquid crystal display (LCD) device. The color filter layer in the LCD device is generally formed on a packaging cover. It generally includes a black matrix (BM), red/green/blue color filters, and an overcoat layer. The BM layer is disposed at both sides of each red/green/blue color filters to shield the light to solve the problem of light leakage between the color filters in the color filter cover plate.

By providing the black matrix between the color filters, the lateral light can be absorbed, which solves the problem of light leakage caused by the optical crosstalk to the adjacent color filters. However, a portion of the lateral light is absorbed by the black matrix causes another light loss issue, resulting in a decrease in the light extraction efficiency of the OLED device. Thus, it is necessary to develop a new color filter cover plate to overcome the drawback of the prior art.

### Technical Problem

One aspect of the present invention provides a color filter cover plate which adopts a novel structural arrangement, which reduces the absorption of the lateral incident light, thereby effectively improving the light extraction efficiency of the display panel.

### SUMMARY OF INVENTION

The technical solution adopted by the present invention is as follows:

A color filter cover plate, including a substrate layer; a plurality of light shielding strips disposed on the substrate layer at intervals; a color filter layer disposed between the light shielding strips; a bank layer disposed on the light shielding strip, and a metal layer disposed on a side surface of each of the light shielding strips or the bank layer facing the color filter layer.

Further, in another embodiment, the bank layer is a portion of the light shielding strip disposed under the bank layer. That is, the bank layer can be a portion of the light shielding strip beyond a height of the color filter layer disposed on one side thereof. In order not to limit the inventive concept of the present invention, the description of the prior art light shielding strip protruding from the color filter layer is separately listed. Thus, according to the inventive concept of the present invention, forming the metal layer on a side surface of the light shielding strip facing the color filter layer. That is, the bank layer is a portion of the light shielding strip beyond a height of the color filter layer on the side thereof.

Further, in another embodiment, wherein the substrate layer includes a glass substrate layer or a flexible substrate layer.

Further, in another embodiment, the light shielding strip has a small contact angle and certain hydrophilicity. For example, the contact angle is less than 90 degrees, and the specific angle can be determined in need and is not limited herein.

Further, in another embodiment, the material of the light shielding strip is a black organic resin material or a black inorganic material. If the black organic resin material is used, the light shielding strip is a black matrix (BM) layer. The black inorganic material includes a metal oxide or a sulfide, and the like, and specifically can be: copper oxide, iron oxide, manganese dioxide, ferroferric oxide, molybdenum sulfide, copper sulfide, or the like, which is not limited herein.

Further, in another embodiment, a thickness of the light shielding strip ranges from 100 nm to 5 μm.

Further, in another embodiment, the bank layer has a larger contact angle and certain hydrophobicity. For example, the contact angle is greater than 90 degrees, and the specific angle can be determined in need and is not limited herein.

Further, in another embodiment, a height of the bank layer ranges from 1 μm to 10 μm.

Further, in another embodiment, the material used in the bank layer is an organic resin material containing fluorine. Specifically, it can be various organic resin materials known in the art. It can be specifically determined in need, and is not limited herein.

Further, in another embodiment, the color filter layer is made of an organic color resist material formed by dispersing a dye in an organic monomer, or a quantum dot ink material formed by dispersing a quantum dot material corresponding to red/green/blue in an organic solvent, preferably an red/green/blue quantum dot ink.

Further, in another embodiment, the material used for the metal layer is a metal or an alloy or a metal oxide or the like having a reflective property, preferably aluminum, silver, magnesium, or the like.

Further, in another embodiment, wherein the metal layer has a reflectance to incident light greater than 80%.

Further, in another embodiment, the metal layer has a thickness ranging from 100 nm to 2000 nm.

Further, in another embodiment, a covering of the metal layer on the light shielding strip or on a side surface of the bank layer facing the groove may be full coverage of its entire surface or may be partial coverage of its entire surface. Specifically, it can be determined in need and is not limited herein.

Further, in another embodiment, a passivation layer is further disposed on a surface of the color filter cover plate.

The passivation layer is a protective layer, and its main function is to avoid the trace gases generated by the organic material in the preparation process of the color filter cover plate influencing the OLED device.

In addition, the contact between the color filter layer and the organic filler in the OLED package can be avoided to increase the service life.

Further, in another embodiment, the passivation layer can be a single layer structure or a stacked layer structure. It can be specifically determined in need and is not limited herein. If adopts a single layer structure, it can be composed of a dense inorganic substance. Specifically, it may be an oxide or nitride of silicon, or an oxide of aluminum, etc., and is prepared by CVD or ALD or sputter method.

Further, the passivation layer of the single layer structure has a thickness ranging from 500 nm to 2000 nm. If adopts a stacked layer structure, it can be formed by sequentially stacking inorganic film layer and organic film layer. The organic film layer is a buffer layer, and the material may be transparent organic polymer resin or SiO₂, etc. The organic film layer has a thickness of 1-20 μm and can be prepared by UP or PECVD method.

Further, a further aspect of the present invention provides a method for preparing the color filter cover plate, including the following steps:

Step S1, providing a substrate, forming the light shielding strips on the substrate at intervals, wherein a groove is formed between the adjacent light shielding strips.

Step S2, forming the bank layer on the light shielding strip.

Step S3, forming the color filter layer in the groove; and

Step S4, forming the metal layer on a side surface of the light shielding strip or the bank layer facing the groove.

Further, the step S1 includes performing a hydrophilic treatment to a surface of the substrate. The specific treatment method can be UV irradiation or plasma treatment for a certain time or modifying the surface of the substrate with a solvent to make it have a hydrophilic effect. The specific method can be determined in need and is not limited herein.

Further, in another embodiment, in step S1 depends on the used material of the light shielding strip, a corresponding embodiment is required. For example, if a black organic resin material is used, all organic film-forming methods such as slit coating, screen printing, spin coating, inkjet printing, or cast film formation methods can be performed. Following the patterning light shielding strips may be formed by exposure and development processes. If an inorganic film is used, a sputter method, a thermal evaporation method, a CVD method, and a PVD method can be performed. The specific preparation method of the light shielding strip can be determined in need and is not limited herein.

Further, in another embodiment, in step S2, the material used in the bank layer is an organic resin material containing fluorine. Specifically, it can be prepared by all organic film-forming methods such as slit coating, screen printing, spin coating, or cast film formation method. And following a patterning bank layer can be formed by exposure and development processes. The specific preparation method can be determined in need and is not limited herein.

Further, in another embodiment, in step S3, the color filter layer includes red/green/blue color resists. The preparation method can be any organic film-forming method such as slit coating, screen printing, spin coating or casting film formation methods. Following, a patterning red/green/blue color resists are formed by exposure and development process or an inkjet printing method. The specific preparation method of the color filter layer can be determined in need and is not limited herein.

Further, in another embodiment, in step S4, the metal layer can be prepared by thermal evaporation or a sputter method and then patterned by a fine pitch photo mask and etching. The specific preparation method can be determined in need and is not limited herein.

Further, in another embodiment, it includes step S5, a passivation layer is further disposed on a surface of the color filter cover plate. The passivation layer is a protective layer, and its main function is to avoid the trace gases generated by the organic material in the preparation process of the color filter cover plate influencing the OLED device. In addition, the contact between the color filter layer and the organic filler in the OLED package can be avoided to increase the service life.

Further, the passivation layer can be a single layer structure or a stacked layer structure. If adopts a single layer structure, it can be composed of a dense inorganic substance. Specifically, it may be an oxide or nitride of silicon, or an oxide of aluminum, etc., and it is prepared by CVD or ALD or sputter method. A thickness of the single layer film is 500-2000 nm. If adopts a stacked layer structure, it may be formed by sequentially stacking inorganic film layer and organic film layer. The organic film layer is a buffer layer, and the material may be a transparent organic polymer resin or SiO₂, etc. The organic film layer has a thickness of 1-20 μm and can be prepared by UP or PECVD methods, etc.

Further, another aspect of the present invention provides a display panel including the color filter cover plate according to the present invention. The display panel may be an OLED display panel but is not limited thereto.

### Beneficial Effect

The present invention relates to a color filter cover plate by introducing a bank layer on the light shielding strip. By combining the two structures, the inks for printing the red/green/blue color filter layer are applied to a specific area during the preparation process. In this way, it is not necessary to use the usual post spacer (PS) structure, thereby simplifying the preparation process.

Further, a metal layer is disposed on a side surface facing the color filter layer. By the color filter cover plate of the present invention, the light of the OLED device emitted to a side of the light shielding strip or the bank layer can be reflected by the metal layer. The lateral light can be emitted out again from the front side of the color filter layer after reflecting, thereby avoiding light loss, and thereby effectively improving the light extraction efficiency of the OLED device.

### DESCRIPTION OF DRAWINGS

In order to more clearly illustrate the technical solutions in the embodiments of the present invention, the following figures described in the embodiments will be briefly introduced. It is obvious that the drawings described below are merely some embodiments of the present invention, other drawings can also be obtained by the person ordinary skilled in the field based on these drawings without doing any creative activity.

FIG. 1 is a schematic structural view of a color filter cover plate according to an embodiment of the present invention after step S1.

FIG. 2 is a schematic view showing a structure of the color filter cover plate of FIG. 1 after step S2.

FIG. 3 is a schematic view showing a structure of the color filter cover plate of FIG. 1 after step S3.

FIG. 4 is a schematic view showing a structure of the color filter cover plate of FIG. 1 after step S4.

FIG. 5 is a schematic view showing a structure of the color filter cover plate of FIG. 1 after step S5.

FIG. 6 is a schematic structural view of a color filter cover plate according to another embodiment of the present invention.

FIG. 7 is a schematic diagram showing an optical path in a color filter cover plate according to an embodiment of the present invention.

### DETAILED DESCRIPTION OF PREFERRED EMBODIMENTS

The color filter cover plate, the preparation method thereof, and the technical solution of the display panel according to the present invention will be further described in detail with reference to the accompanying drawings and embodiments.

The present invention relates to a structure of a color filter cover plate, and to a method for preparing the same. In order to avoid unnecessary description, the structure of the color filter cover plate according to the present invention will be described in conjunction with the preparation method.

An embodiment of the present invention provides a method of preparing a color filter cover plate according to the present invention, including the following steps:

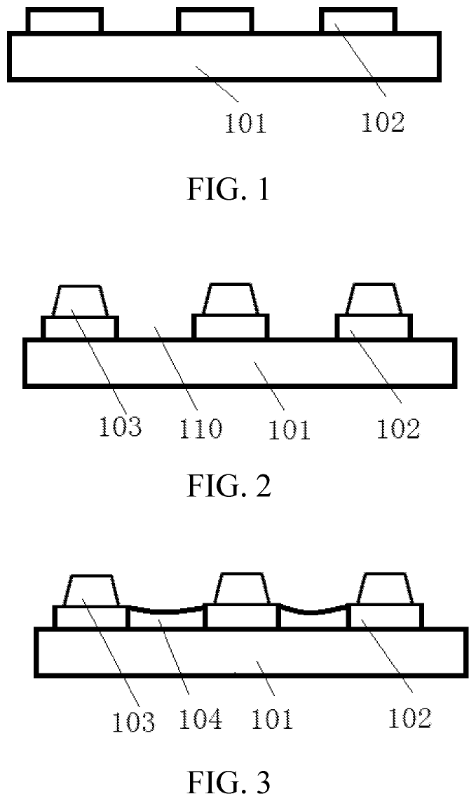

Step S1, providing a glass substrate 101 and performing UV treatment on the glass substrate 101 to form a hydrophilic surface. Following, a copper sulfide of 2-3 μm thick is deposited on the glass substrate 101 as a light shielding strip 102 by a sputter process, and the completed structure is shown in FIG. 1.

Step S2, coating a fluorine-containing organic photoresist material on the light shielding strip 102 by a slit coating process. After exposure and development processes, a bank layer 103 structure having a hydrophobic surface of 2-5 μm is obtained. A groove structure 110 is formed between the bank layer 103 and the light shielding strip therebelow, and the completed structure is shown in FIG. 2.

Step S3, dropping an ink material for preparing a quantum dot red/green/blue color filter layer to the groove 110 by an inkjet printing (IJP) process. Each of the red/green/blue color filter layers 104 having good uniformity are formed by the evaporation process under reduced pressure and a heating process. The completed structure is shown in FIG. 3

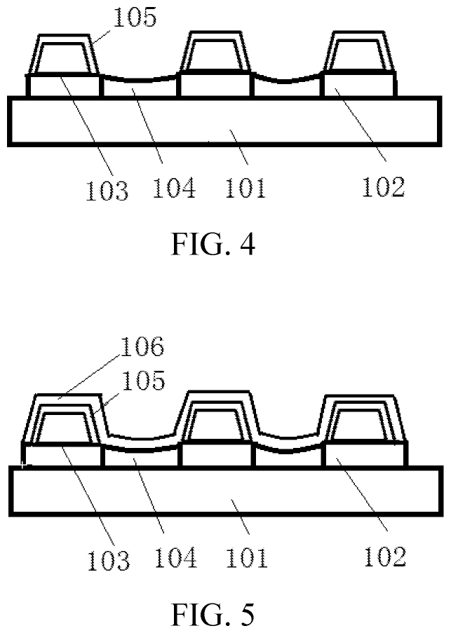

Step S4, preparing a metal layer 105 on the bank layer 103. It uses thermal evaporation combined with a fine pitch photo mask technology to form a 200 nm thick metal silver as a metal layer. The completed structure is shown in FIG. 4.

Step S5, forming a 500-800 nm thick SiN passivation layer on a surface of the cover plate by a PECVD method as a protective layer of the color filter cover plate. The completed structure is shown in FIG. 5. The structure as shown in FIG. 5 is also a complete structure of the color filter cover plate provided by an embodiment of the present invention.

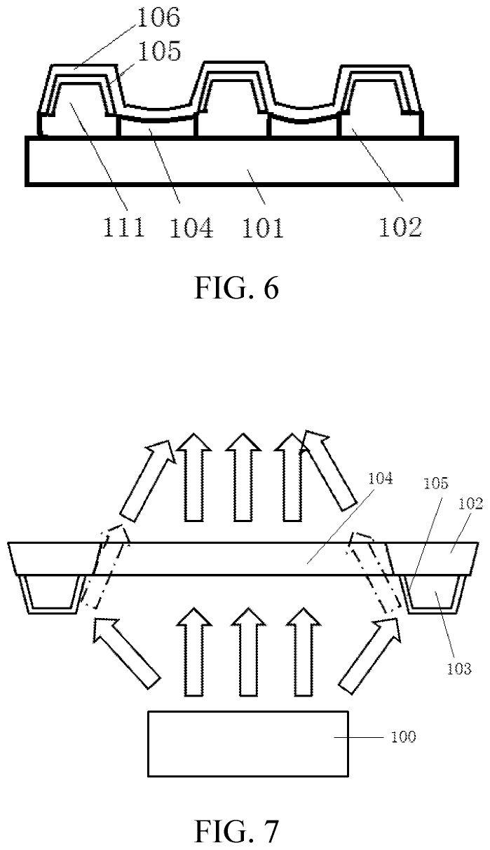

Further, in another embodiment, it provides another structure of a color filter cover plate according to the present invention, which adopts a novel structure arrangement between the bank layer and the light shielding strip. The structure is shown in FIG. 6.

As shown in FIG. 6, the bank layer and the light shielding strip are combined into an integral structure composed of the same material. That is, the position of the original bank layer is replaced by the convex portion 111 of the light shielding strip 102, wherein the metal layer 105 is disposed on a surface of the convex portion 111.

Further, in another embodiment, the arrangement of the metal layer 105 does not need to completely cover the surface of the bank layer 103. The inventive concept of the present invention can be realized only by forming the metal layer 105 on a side surface of the bank layer 103 facing the color filter layer 104.

Please refer to FIG. 7, which illustrates an optical path diagram when the color filter cover plate of the present invention is applied to a display panel. The display panel is exemplified by an OLED display panel but is not limited thereto. As shown in FIG. 7, the light generated by the OLED device 100 of the display panel is incident to the color filter cover plate. As indicated by the arrow in the figure, the emitted light directly passes through the color filter layer 103 and the color filter cover plate. The laterally emitted light, after being reflected by the metal layer 105 disposed on a side of the bank layer 104, can be reused, and cab also be emitted out from the color filter layer 103 and the color filter cover plate. In this way, at least a portion of the lateral incident light originally absorbed by the light shielding strip can be utilized again, thereby effectively improving the light extraction efficiency of the OLED device 100.

The present invention relates to a color filter cover plate by introducing a bank layer on the light shielding strip. By combining the two structures, the inks for printing the red/green/blue color resists are applied to a specific area during the preparation process. In this way, it is not necessary to use the usual post spacer (PS) structure, thereby simplifying the preparation process.

The description of the above exemplary embodiments is only for the purpose of understanding the invention. It is to be understood that the present invention is not limited to the disclosed exemplary embodiments. It is obvious to those skilled in the art that the above exemplary embodiments may be modified without departing from the scope and spirit of the present invention.

What is claimed is:

1. A color filter cover plate, comprising
a substrate layer;
a plurality of light shielding strips disposed on the substrate layer at intervals;
a color filter layer disposed between the light shielding strips;
a bank layer disposed on the light shielding strips; and
a metal layer disposed on a side surface of each of the light shielding strips or the bank layer facing the color filter layer.

2. The color filter cover plate according to claim 1, wherein the metal layer has a reflectance to incident light greater than 80%.

3. The color filter cover plate according to claim 1, wherein a thickness of the metal layer ranges from 100 nm to 2000 nm.

4. The color filter cover plate according to claim 1, wherein the bank layer is a portion of the light shielding strip disposed under the bank layer.

5. The color filter cover plate according to claim 1, wherein a thickness of each of the light shielding strips ranges from 100 nm to 5 μm.

6. The color filter cover plate according to claim 1, wherein a height of the bank layer ranges from 1 μm to 10 μm.

7. The color filter cover plate according to claim 1, wherein the bank layer is made of an organic resin material containing a fluorine element.

8. A method of preparing the color filter cover plate according to claim 1, comprising:
step S1, providing a substrate, forming the light shielding strips on the substrate at intervals, wherein a groove is formed between adjacent light shielding strips;
step S2, forming the bank layer on the light shielding strip;
step S3, forming the color filter layer in the groove; and
step S4, forming the metal layer on a side surface of each of the light shielding strips or the bank layer facing the groove.

9. The method of preparing the color filter cover plate according to claim 8, wherein the step S1 further comprises providing a hydrophilic treatment to a surface of the substrate.

10. A display panel, comprising the color filter cover plate according to claim 1.
